(19) United States
(12) Patent Application Publication
(10) Pub. No.: US 2026/0013358 A1
(43) Pub. Date: Jan. 8, 2026

(54) DISPLAY DEVICE

(71) Applicant: Sharp Display Technology Corporation, Kameyama City, Mie (JP)

(72) Inventors: Eiji KOIKE, Kameyama City, Mie (JP); Junya SHIMADA, Kameyama City, Mie (JP); Norio MUROFUSHI, Kameyama City, Mie (JP); Yuto TSUKAMOTO, Kameyama City, Mie (JP)

(21) Appl. No.: 18/881,871

(22) PCT Filed: Aug. 10, 2022
(86) PCT No.: PCT/JP2022/030580

§ 371 Date: Jan. 7, 2025

(51) Int. Cl. H10K 59/35

(52) U.S. Cl. CPC H10K 59/353; H10K 59/351

(57) ABSTRACT

A display device includes at least one light-emitting unit that is a quadrilateral in a plan view. The at least one light-emitting unit includes a first light-emitting portion configured to emit light of a first color and disposed facing a portion including a first corner, a second corner, and a third corner of the quadrilateral, a second light-emitting portion configured to emit light of a second color and disposed facing a fourth corner of the quadrilateral, and a third light-emitting portion configured to emit light of a third color with a luminosity higher than both a luminosity of the first color and a luminosity of the second color, the third light-emitting portion being disposed closer to a center of the quadrilateral than the first light-emitting portion and the second light-emitting portion.

### TECHNICAL FIELD

The disclosure relates to a display device.

### BACKGROUND ART

PTL 1 discloses a rectangular pixel, in which a green subpixel is disposed at a center portion of the rectangular pixel, and an area of a blue subpixel is larger than an area of the green subpixel and an area of a red subpixel.

CITATION LIST

### Patent Literature

PTL 1: JP 2016-9636 A

### SUMMARY

### Technical Problem

In the pixel disclosed in PTL 1, a layer containing a material capable of emitting light is separately patterned for each of the red subpixel, the green subpixel, and the blue subpixel. In the pixel, since it is necessary to limit the area of each subpixel in order to avoid color mixing of light, the aperture ratio is reduced.

Thus, in the technique disclosed in PTL 1, it is difficult to realize a display device having a long service life due to rapid deterioration of the blue subpixel in particular.

### Solution to Problem

A display device according to an aspect of the disclosure includes: at least one light-emitting unit that is a quadrilateral in a plan view, wherein the at least one light-emitting unit includes a first light-emitting portion configured to emit light of a first color and disposed facing a portion including a first corner, a second corner, and a third corner of the quadrilateral; a second light-emitting portion configured to emit light of a second color and disposed facing a fourth corner of the quadrilateral; and a third light-emitting portion configured to emit light of a third color with a luminosity higher than both a luminosity of the first color and a luminosity of the second color, the third light- emitting portion being disposed closer to a center of the quadrilateral than the first light-emitting portion and the second light-emitting portion.

### Advantageous Effects of Disclosure

According to an aspect of the disclosure, it is possible to realize a display device having a long service life.

### BRIEF DESCRIPTION OF DRAWINGS

FIG. 1 is a schematic diagram of a display device according to an aspect of the disclosure.

FIG. 2 is a plan view illustrating a schematic configuration of a light-emitting unit according to a first embodiment of the disclosure.

FIG. 3 is a schematic cross-sectional view illustrating the light-emitting unit according to the first embodiment of the disclosure.

FIG. 4 is (1) a plan view illustrating the arrangement of a first anode electrode, a second anode electrode, a third anode electrode, a first light-emitting material layer, a second light-emitting material layer, and a third light-emitting material layer; (2) a plan view illustrating the relative arrangement of the first anode electrode, the second anode electrode, and the third anode electrode; and (3) a plan view illustrating the relative arrangement of the first light-emitting material layer, the second light-emitting material layer, and the third light-emitting material layer.

FIG. 5 is a plan view illustrating a schematic configuration of a light-emitting unit according to a second embodiment of the disclosure.

FIG. 6 is a plan view illustrating a schematic configuration of a light-emitting unit according to a third embodiment of the disclosure.

FIG. 7 is a plan view illustrating a schematic configuration of a light-emitting-unit unit according to a fourth embodiment of the disclosure.

FIG. 8 is a plan view illustrating a schematic configuration of a light-emitting-unit unit according to a fifth embodiment of the disclosure.

FIG. 9 is an example in which the light-emitting-unit units according to the fifth embodiment of the disclosure are arranged in two rows and two columns.

FIG. 10 is an example in which the light-emitting unit according to the third embodiment of the disclosure is applied to FIG. 9 as each light-emitting unit.

FIG. 11 illustrates three light-emitting-unit units according to Examples.

FIG. 12 illustrates three light-emitting-unit units according to Comparative Examples.

FIG. 13 is a table indicating the area and the aperture ratio of the first light-emitting portion for each light-emitting unit of the light-emitting-unit units totaling six as illustrated in FIGS. 11 and 12.

### DESCRIPTION OF EMBODIMENTS

Embodiments for implementing the disclosure will be described. For convenience of description, members having the same functions as members described earlier may be denoted by the same reference numerals and signs, and the description thereof will not be repeated.

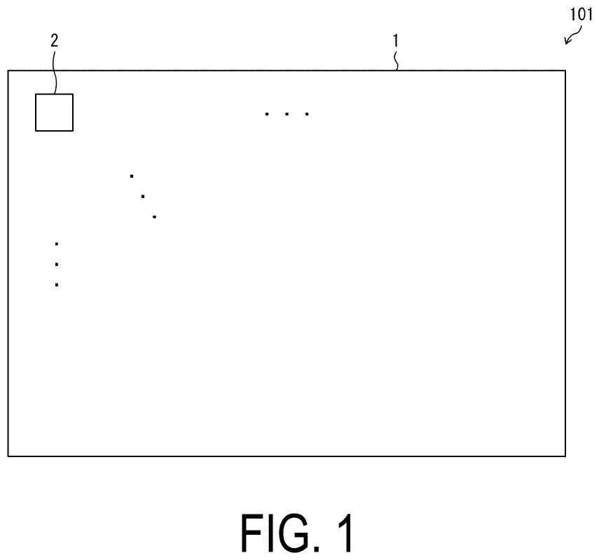

FIG. 1 is a schematic diagram of a display device 101 according to an aspect of the disclosure. The display device 101 may be an organic light-emitting diode (OLED) display device or a quantum dot light-emitting diode (QLED) display device. The display device 101 includes a display panel 1. The display panel 1 includes at least one light-emitting unit 2, and here includes a large number of light-emitting units 2 arranged in rows and columns.

The light-emitting unit 2 emits light including at least one of light of a first color, light of a second color, and light of a third color. The luminosity of the third color is higher than the luminosity of the first color. The luminosity of the third color is higher than the luminosity of the second color. The luminosity of the first color may be lower than the luminosity of the second color. The first color may be blue. The second color may be red, and the third color may be green. Here, the first color is blue, the second color is red, and the third color is green. The light-emitting unit 2 may be one pixel. The luminosity may typically be relative luminosity based on photopic vision.

### First Embodiment

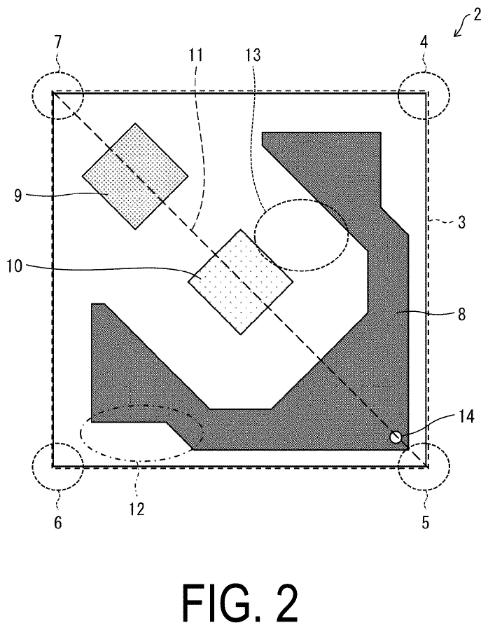

FIG. 2 is a plan view illustrating a schematic configuration of the light-emitting unit 2 according to the first embodiment of the disclosure.

The light-emitting unit 2 has a quadrilateral shape in a plan view. This quadrilateral is illustrated in FIG. 2 as a quadrilateral 3. The quadrilateral 3 includes a first corner 4, a second corner 5, a third corner 6, and a fourth corner 7.

The light-emitting unit 2 includes a first light-emitting portion 8, a second light-emitting portion 9, and a third light-emitting portion 10. In a case where the light-emitting unit 2 is one pixel, each of the first light-emitting portion 8, the second light-emitting portion 9, and the third light-emitting portion 10 may be a subpixel included in the one pixel.

The first light-emitting portion 8 emits light of the first color (blue). The second light-emitting portion 9 emits light of the second color (red). The third light-emitting portion 10 emits light of the third color (green).

The first light-emitting portion 8 is disposed facing a portion including the first corner 4, the second corner 5, and the third corner 6 of the quadrilateral 3. The second light-emitting portion 9 is disposed facing the fourth corner 7 of the quadrilateral 3. The third light-emitting portion 10 is disposed closer to the center of the quadrilateral 3 than the first light-emitting portion 8. The third light-emitting portion 10 is disposed closer to the center of the quadrilateral 3 than the second light-emitting portion 9.

In the light-emitting unit 2, the maximum aperture ratio of the first light-emitting portion 8 can be secured by taking into consideration the arrangement of the second light-emitting portion 9 and the third light-emitting portion 10 in the light-emitting unit 2. Thus, according to the light-emitting unit 2, it is possible to realize the display device 101 having a long service life. The third light-emitting portion 10 is disposed at the center of the quadrilateral 3 in the light-emitting unit 2, and the second light-emitting portion 9 is disposed facing the fourth corner 7 in order to avoid color mixing of the light of the second color and the light of the third color. The second light-emitting portion 9 and the third light-emitting portion 10 are surrounded by the first light-emitting portion 8 in a U-shape (approximate shape). Thus, an area of the first light-emitting portion 8 which may tend to have a short service life can be maximized.

With the light-emitting unit 2, it is possible to achieve a shape of the first light-emitting portion 8 (maximum aperture ratio) which enables the service life of the first light-emitting portion 8 to be maximized. Since the light-emitting unit 2 includes the first light-emitting portion 8, the second light-emitting portion 9, and the third light-emitting portion 10, the display device 101 equipped with the light-emitting unit 2 can realize high display quality (jitter prevention and color edge prevention).

The second light-emitting portion 9 and the third light-emitting portion 10 may be disposed on a common diagonal line 11 of the quadrilateral 3. Thus, the arrangement of the second light-emitting portion 9 and the third light-emitting portion 10 is organized in the light-emitting unit 2, so that the aperture ratio of the first light-emitting portion 8 can be further increased.

A missing portion 12 of the first light-emitting portion 8 may be formed facing any one side of the quadrilateral 3. Accordingly, it is possible to reduce the possibility that the first light-emitting portion 8 of a certain light-emitting unit 2 overlaps with the second light-emitting portion 9 and/or the third light-emitting portion 10 of another light-emitting unit 2 adjacent to the certain light-emitting unit 2. Thus, color mixing of the light of the first color with the light of the second color and/or the light of the third color can be avoided.

The portion of the first light-emitting portion 8 disposed facing the first corner 4, the portion of the first light-emitting portion 8 disposed facing the second corner 5, and the portion of the first light-emitting portion 8 disposed facing the third corner 6 may be continuous with each other. FIG. 2 illustrates an example in which these three portions are continuous with each other to form one first light-emitting portion 8.

Among the first light-emitting portion 8, the second light-emitting portion 9, and the third light-emitting portion 10, two adjacent light-emitting portions are referred to as a first target light-emitting portion and a second target light-emitting portion. Here, the first light-emitting portion 8 is set as the first target light-emitting portion, and the third light-emitting portion 10 is set as the second target light-emitting portion. At this time, light may not be emitted between the first light-emitting portion 8 (first target light-emitting portion) and the third light-emitting portion 10 (second target light-emitting portion), that is, by a gap 13.

FIG. 2 illustrates a contact hole 14 for the first light-emitting portion 8.

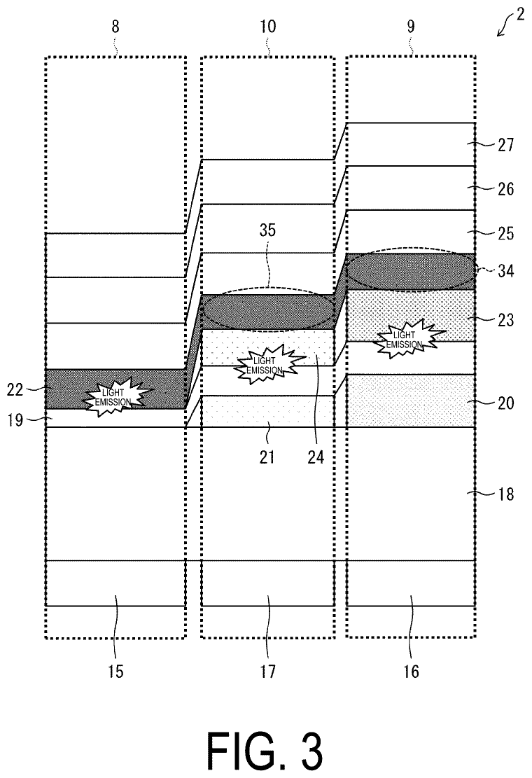

FIG. 3 is a schematic cross-sectional view of the light-emitting unit 2. The light-emitting unit 2 includes a first anode electrode 15, a second anode electrode 16, a third anode electrode 17, a hole injection layer 18, a first hole transport layer 19, a second hole transport layer 20, a third hole transport layer 21, a first light-emitting material layer 22, a second light-emitting material layer 23, a third light-emitting material layer 24, an electron transport layer 25, an electron injection layer 26, and a cathode electrode 27. At least two of the first hole transport layer 19, the second hole transport layer 20, and the third hole transport layer 21 may be structurally integrally formed. The hole injection layer 18, the electron transport layer 25, the electron injection layer 26, and the cathode electrode 27 may be provided independently for each of the first light-emitting portion 8, the second light-emitting portion 9, and the third light-emitting portion 10.

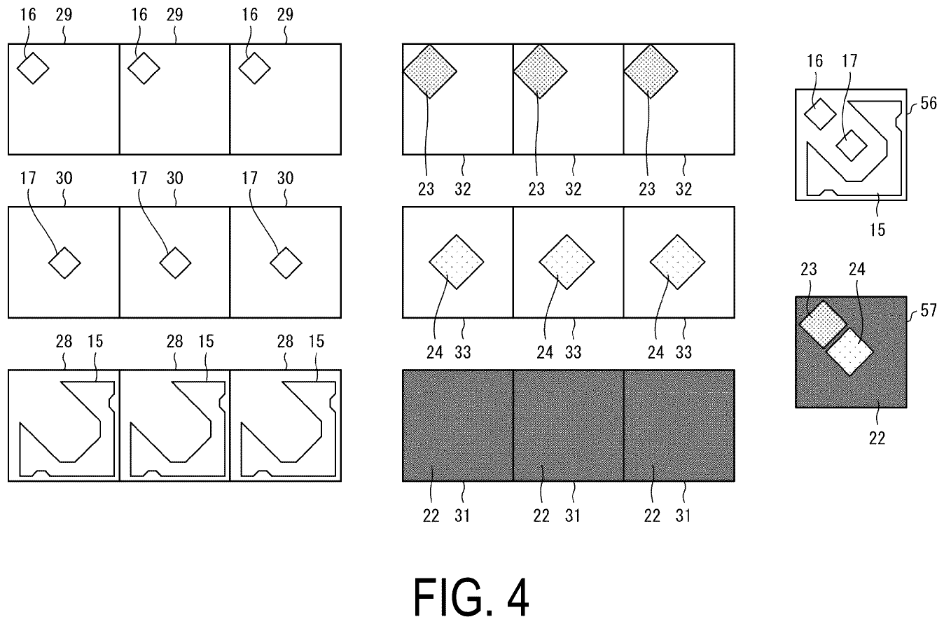

FIG. 4 is (1) a plan view illustrating the arrangement of the first anode electrode 15, the second anode electrode 16, the third anode electrode 17, the first light-emitting material layer 22, the second light-emitting material layer 23, and the third light-emitting material layer 24; (2) a plan view illustrating the relative arrangement of the first anode electrode 15, the second anode electrode 16, and the third anode electrode 17; and (3) a plan view illustrating the relative arrangement of the first light-emitting material layer 22, the second light-emitting material layer 23, and the third light-emitting material layer 24.

FIG. 4 illustrates a total of six types of quadrilaterals 28 to 33, each corresponding to one quadrilateral 3 on a one-to-one basis. In FIG. 4, the arrangement of the first anode electrode 15 in the quadrilateral 3 is illustrated in the quadrilateral 28. In FIG. 4, the arrangement of the second anode electrode 16 in the quadrilateral 3 is illustrated in the quadrilateral 29. In FIG. 4, the arrangement of the third anode electrode 17 in the quadrilateral 3 is illustrated in the quadrilateral 30. In FIG. 4, the arrangement of the first light-emitting material layer 22 in the quadrilateral 3 is illustrated in the quadrilateral 31. In FIG. 4, the arrangement of the second light-emitting material layer 23 in the quadrilateral 3 is illustrated in the quadrilateral 32. In FIG. 4, the arrangement of the third light-emitting material layer 24 in the quadrilateral 3 is illustrated in the quadrilateral 33.

In FIG. 4, three quadrilaterals 31 are drawn in a continuous state. This corresponds to three quadrilaterals 3 and thus three light-emitting units 2 being disposed continuously. The same applies to the quadrilaterals 28 to 30, 32, and 33.

FIG. 4 also illustrates a total of two types of quadrilaterals 56 and 57, each corresponding to one quadrilateral 3 on a one-to-one basis. In FIG. 4, the relative arrangement of the first anode electrode 15, the second anode electrode 16 and the third anode electrode 17 in the quadrilateral 3 is illustrated in the quadrilateral 56. In FIG. 4, the relative arrangement of the first light-emitting material layer 22, the second light-emitting material layer 23 and the third light-emitting material layer 24 in the quadrilateral 3 is illustrated in the quadrilateral 57.

The first light-emitting material layer 22 is a layer containing a material capable of emitting light of the first color. The first light-emitting material layer 22 is indicated by “light-emitting material layer” without an ordinal number. The second light-emitting material layer 23 is a layer containing a material capable of emitting light of the second color. The third light-emitting material layer 24 is a layer containing a material capable of emitting light of the third color. Each of the first light-emitting material layer 22, the second light-emitting material layer 23, and the third light-emitting material layer 24 may be a so-called electroluminescence layer including an OLED or a QLED.

The first light-emitting material layer 22 is formed entirely in the lateral direction in the cross section illustrated in FIG. 3, and is thus formed substantially entirely in the quadrilateral 31 (quadrilateral 3). A portion 34 of the first light-emitting material layer 22 overlaps with the second light-emitting material layer 23 containing a material capable of emitting light of the second color. A portion 35 of the first light-emitting material layer 22 overlaps with the third light-emitting material layer 24 containing a material capable of emitting light of the third color. Each of the portion 34 of the first light-emitting material layer 22 and the portion 35 of the first light-emitting material layer 22 may be non-emitting.

The configuration in which the first light-emitting material layer 22 is formed substantially entirely in the quadrilateral 3 can be referred to as commonization of the first light-emitting material layer 22. In each of the first light-emitting material layer 22, the second light-emitting material layer 23, and the third light-emitting material layer 24, recombination of electrons and holes occurs only in a light-emitting portion thereof. According to the commonization of the first light-emitting material layer 22, it is not necessary to separately pattern the first light-emitting material layer 22 with respect to the second light-emitting material layer 23 and the third light-emitting material layer 24. Thus, the configuration of the light-emitting unit 2 illustrated in FIG. 2 can be easily realized.

The first light-emitting material layer 22 is formed on substantially the entirety of the three quadrilaterals 31 (quadrilaterals 3) that are continuous with each other. The first light-emitting material layers 22 formed on substantially the entirety of the three quadrilaterals 31 (quadrilaterals 3) may be continuous with each other.

As with the first light-emitting material layer 22, the first hole transport layer 19 is also formed entirely in the lateral direction in the cross section illustrated in FIG. 3, and is thus formed substantially entirely in the quadrilateral 31 (quadrilateral 3). A portion of the first hole transport layer 19 overlaps with the second hole transport layer 20, and another portion of the first hole transport layer 19 overlaps with the third hole transport layer 21.

In a plan view of the light-emitting unit 2, each of the shape of the first light-emitting portion 8, the shape of the second light-emitting portion 9, and the shape of the third light-emitting portion 10 may be defined by the shape of the corresponding electrode. The electrode corresponding to the first light-emitting portion 8 may be the first anode electrode 15. The electrode corresponding to the second light-emitting portion 9 may be the second anode electrode 16. The electrode corresponding to the third light-emitting portion 10 may be the third anode electrode 17.

### Second Embodiment

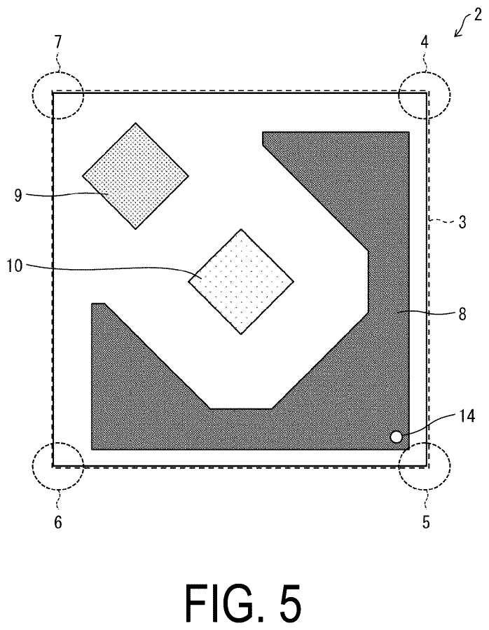

FIG. 5 is a plan view illustrating a schematic configuration of the light-emitting unit 2 according to the second embodiment of the disclosure.

The light-emitting unit 2 according to the second embodiment of the disclosure is different from the light-emitting unit 2 according to the first embodiment of the disclosure in that the missing portion 12 of the first light-emitting portion 8 is not formed. Accordingly, the aperture ratio of the first light-emitting portion 8 of the light-emitting unit 2 according to the second embodiment of the disclosure can be made larger than the aperture ratio of the first light-emitting portion 8 of the light-emitting unit 2 according to the first embodiment of the disclosure.

### Third Embodiment

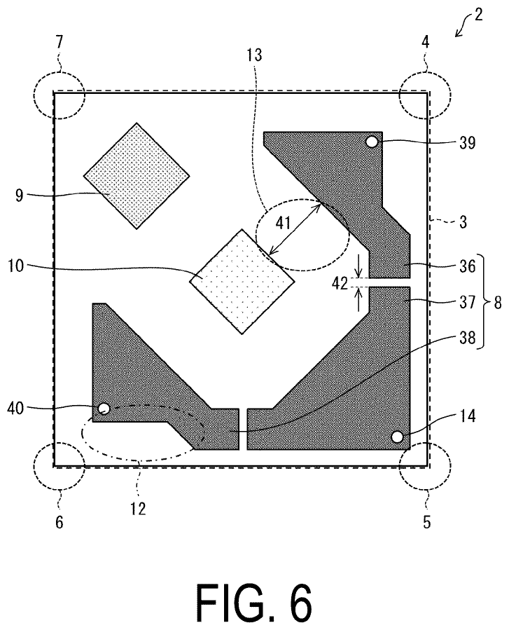

FIG. 6 is a plan view illustrating a schematic configuration of the light-emitting unit 2 according to the third embodiment of the disclosure.

The light-emitting unit 2 according to the third embodiment of the disclosure is different from the light-emitting unit 2 according to the first embodiment of the disclosure in the following points. In the light-emitting unit 2 according to the third embodiment of the disclosure, the first light-emitting portion 8 is divided into three (a plurality of) small regions 36 to 38. The contact hole 14 functions as a contact hole for the small region 37. In the light-emitting unit 2 according to the third embodiment of the disclosure, a contact hole 39 for the small region 36 and a contact hole 40 for the small region 38 are formed. In brief, the first light-emitting portion 8 is divided into the plurality of small regions 36 to 38 which are electrically isolated from each other.

Accordingly, for example, in a case where the small region 36 becomes a bright spot defect due to a foreign substance or the like, it is possible to prevent the entire first light-emitting portion 8 from being turned off (becoming a black spot) by performing black spot correction only on the small region 36 (releasing leakage and preventing a current increase). Thus, it is possible to realize the light-emitting unit 2 in which deterioration in display quality is suppressed.

The number of divisions of the first light-emitting portion 8 (in other words, the number of small regions) is not limited to three and may be any natural number equal to or greater than two.

Among the first light-emitting portion 8, the second light-emitting portion 9, and the third light-emitting portion 10, two adjacent light-emitting portions are referred to as a first target light-emitting portion and a second target light-emitting portion. Here, the first light-emitting portion 8 is set as the first target light-emitting portion, and the third light-emitting portion 10 is set as the second target light-emitting portion. At this time, light may not be emitted between the first light-emitting portion 8 (first target light-emitting portion) and the third light-emitting portion 10 (second target light-emitting portion), that is, by a gap 13.

Furthermore, a minimum value 41 of the separation distance between the first light-emitting portion 8 (first target light-emitting portion) and the third light-emitting portion 10 (second target light-emitting portion) may be larger than a minimum value 42 of the separation distance between two adjacent small regions 36 to 38. In other words, the minimum value of the separation distance is the length of a line segment connecting the closest connection portions by the shortest distance. In order to avoid color mixing of light, the minimum value (for example, the minimum value 41) of the separation distance between the first target light-emitting portion and the second target light-emitting portion may be not less than 15 μm and not greater than 20 μm regardless of which light-emitting portion is the first target light-emitting portion and the second target light-emitting portion.

### Fourth Embodiment

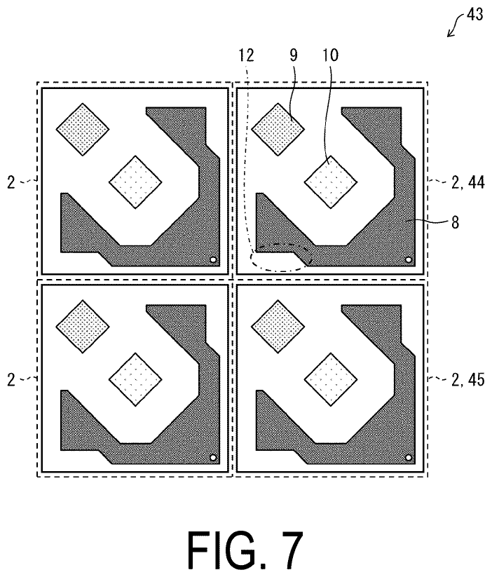

FIG. 7 is a plan view illustrating a schematic configuration of the light-emitting-unit unit 43 according to the fourth embodiment of the disclosure. The light-emitting-unit unit 43 is provided in the display device 101 (see FIG. 1) and includes two or more (a plurality of) light-emitting units 2.

The light-emitting-unit unit 43 includes four (a plurality of) light-emitting units 2. The four light-emitting units 2 are arranged in the same orientation. In this case, in order to avoid color mixing of light, the missing portion 12 of the first light-emitting portion 8 may be formed. Two of the four light-emitting units 2 are referred to as a first light-emitting unit 44 and a second light-emitting unit 45. The light-emitting-unit unit 43 includes the first light-emitting unit 44 and the second light-emitting unit 45, and the first light-emitting portion 8 of the first light-emitting unit 44 and the second light-emitting portion 9 of the second light-emitting unit 45 may face each other across the missing portion 12 of the first light-emitting portion 8 of the first light-emitting unit 44.

### Fifth Embodiment

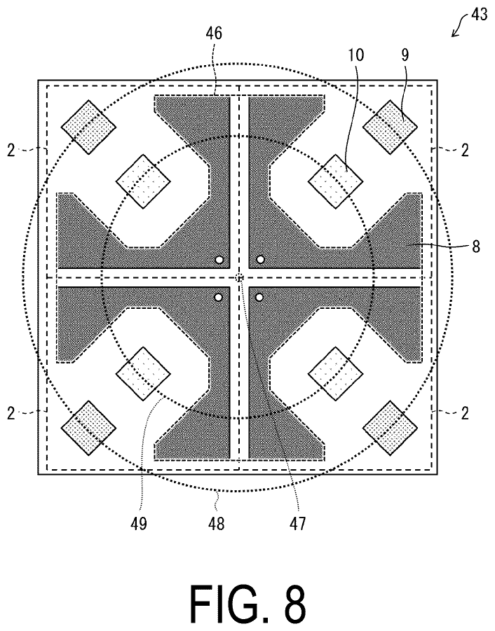

FIG. 8 is a plan view illustrating a schematic configuration of the light-emitting-unit unit 43 according to the fifth embodiment of the disclosure.

The light-emitting-unit unit 43 according to the fifth embodiment of the disclosure is different from the light-emitting-unit unit 43 according to the fourth embodiment of the disclosure in the following points. The light-emitting-unit unit 43 includes four light-emitting units 2. The first light-emitting portions 8 of the four light-emitting units 2 are arranged to form a cross. The cross is illustrated in FIG. 8 as a cross 46. In other words, the light-emitting-unit unit 43 according to the fifth embodiment of the disclosure includes four light-emitting units 2 arranged in four rotationally symmetrical positions.

Accordingly, the first light-emitting portion 8 of a certain light-emitting unit 2 is not located close to the second light-emitting portion 9 or the third light-emitting portion 10 of another light-emitting unit 2 adjacent to the certain light-emitting unit 2. Thus, since it is not necessary to form the missing portion 12 of the first light-emitting portion 8 in the certain light-emitting unit 2, it is possible to increase the aperture ratio of the first light-emitting portion 8.

The second light-emitting portions 9 of the four light-emitting units 2 may be arranged on a first circle 48 centered on a center 47 of the cross 46. The third light-emitting portions 10 of the four light-emitting units 2 may be arranged on a second circle 49 centered on the center 47 of the cross 46.

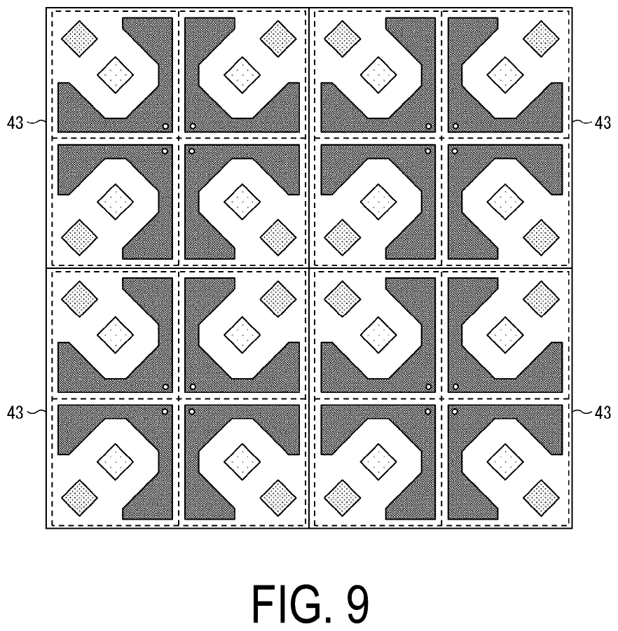

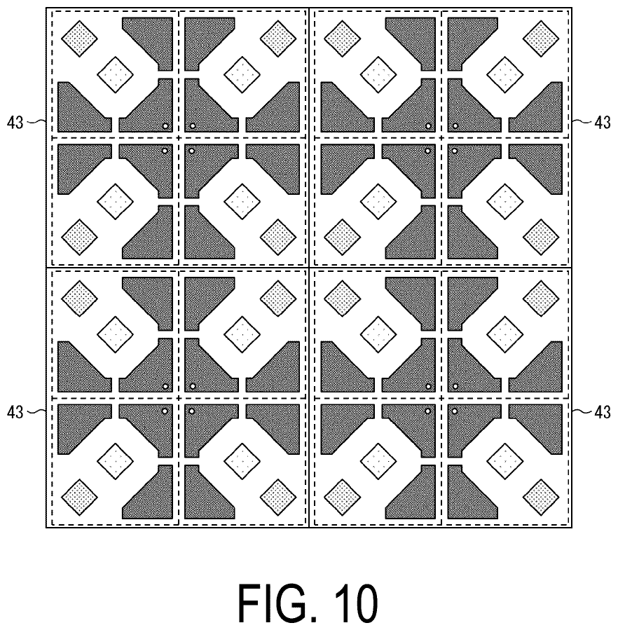

FIG. 9 is an example in which the light-emitting-unit units 43 according to the fifth embodiment of the disclosure are arranged in two rows and two columns. By disposing the second light-emitting portion 9 at the end in the light-emitting-unit unit 43, the requirement for the accuracy of separately patterning the second light-emitting material layer 23 is relaxed. FIG. 10 is an example in which the light-emitting unit 2 according to the third embodiment of the disclosure is applied to FIG. 9 as each light-emitting unit 2.

### Appendix

The light-emitting unit 2 is designed in consideration of commonization of the first light-emitting material layer 22 described above. Because it is not necessary to separately pattern the first light-emitting material layer 22, there is less restriction on the planar shape of the first light-emitting portion 8. When the commonization of the first light-emitting material layer 22 is applied, it is possible to realize the structure of the first light-emitting portion 8 which has been difficult to realize by the technique of forming the first light-emitting material layer 22 using a vapor deposition mask. This is because it is not necessary to secure the rib area of the vapor deposition mask, which leads to an improvement in the degree of freedom of the planar shape of the first light-emitting portion 8.

In the light-emitting unit 2, the second light-emitting material layer 23 and the third light-emitting material layer 24 are separately patterned so that the aperture ratio of the first light-emitting portion 8 can be maximized in an arrangement for preventing color mixing, and the third light-emitting portion 10 is disposed at the center of the quadrilateral 3, thereby preventing color edge display defects.

In order to avoid color mixing of the first color light with the second color light and/or the third color light, it is effective to form the missing portion 12 of the first light-emitting portion 8.

In the light-emitting-unit unit 43 according to the fifth embodiment of the disclosure, the four light-emitting units 2 are arranged so as to be rotated by 0°, 90°, 180°, and 270°, respectively. Accordingly, the wiring in the source direction and the wiring in the gate direction of the first light-emitting portion 8 can be integrated, and a significant improvement in the manufacturing process can be expected. When the four light-emitting units 2 are arranged in this manner, the first light-emitting portions 8 are less likely to be discontinuous and are evenly arranged. Thus, the perception of dots is less likely to occur, and high display quality can be realized. In addition, by collecting the plurality of second light-emitting portions 9 in one place, it is possible to easily manufacture a vapor deposition mask for forming the second light-emitting material layer 23.

### Aperture Ratio Comparison

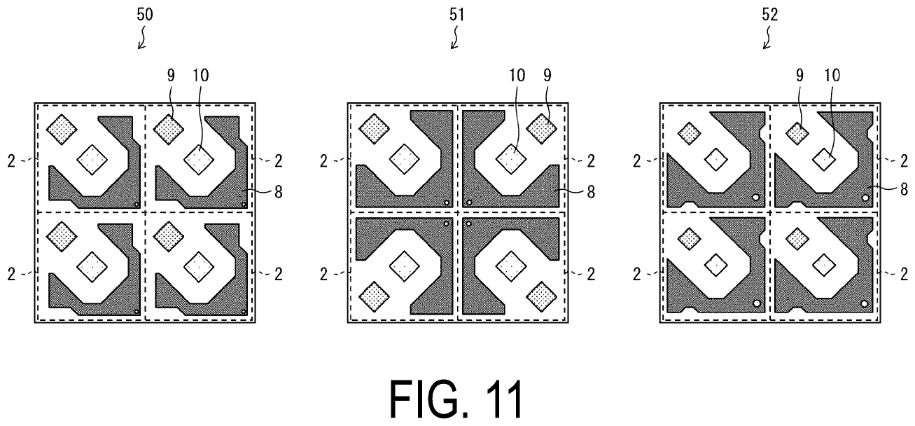

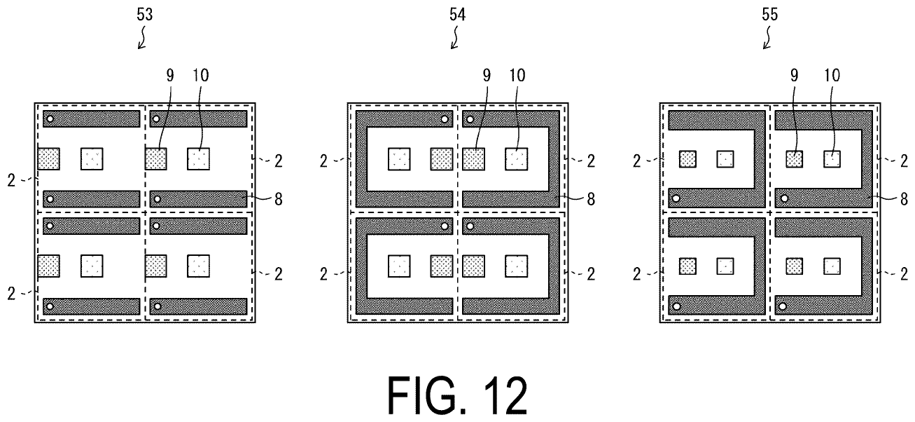

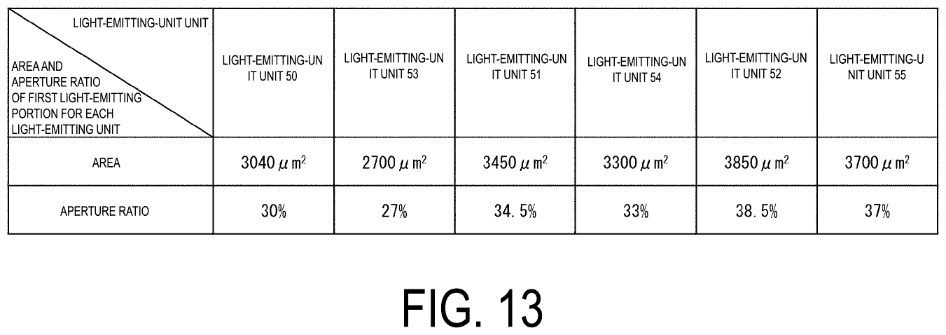

FIG. 11 illustrates light-emitting-unit units 50 to 52 according to Examples. FIG. 12 illustrates light-emitting-unit units 53 to 55 according to Comparative Examples. FIG. 13 is a table indicating the area and the aperture ratio of the first light-emitting portion 8 for each light-emitting unit 2 of the light-emitting-unit units 50 to 55. Each of the light-emitting-unit units 53 to 55 according to the Comparative Examples is also referred to as the light-emitting unit 2 in order to simplify the description.

The light-emitting unit 2 is assumed to be a square having a side length of 100 μm in a plan view. In other words, the area of the light-emitting unit 2 is 10000 μm² in a plan view. In addition, in order to avoid color mixing, 20 μm or more is secured for each of the minimum value of the separation distance between the first light-emitting portion 8 and the second light-emitting portion 9, the minimum value of the separation distance between the second light-emitting portion 9 and the third light-emitting portion 10, and the minimum value of the separation distance between the third light-emitting portion 10 and the first light-emitting portion 8.

The light-emitting-unit unit 50 has the same configuration as that of the light-emitting-unit unit 43 according to the fourth embodiment of the disclosure.

A comparative example to the light-emitting-unit unit 50 is the light-emitting-unit unit 53. When the plurality of light-emitting units 2 are arranged in the same orientation, it is difficult to vertically provide the first light-emitting portion 8 in the light-emitting-unit unit 53 in order to avoid both color mixing of light of the first color and light of the second color and color mixing of light of the first color and light of the third color. Thus, in each light-emitting unit 2 of the light-emitting-unit unit 53, the first light-emitting portion 8 has two belt-like shapes extending laterally.

When the light-emitting-unit unit 50 and the light-emitting-unit unit 53 are compared with each other in terms of the area and the aperture ratio of the first light-emitting portion 8 for each light-emitting unit 2, it is found that the light-emitting-unit unit 50 has larger values.

The light-emitting-unit unit 51 has the same configuration as that of the light-emitting-unit unit 43 (see FIG. 8) according to the fifth embodiment of the disclosure.

A comparative example to the light-emitting-unit unit 51 is the light-emitting-unit unit 54. Since the light-emitting-unit unit 54 has a structure in which the second light-emitting portions 9 of the two light-emitting units 2 are adjacent to each other, it is not necessary to avoid color mixing of the light of the first color and the light of the second color. Thus, in the light-emitting-unit unit 54, unlike in the light-emitting-unit unit 53, the first light-emitting portion 8 is formed in a U-shape. Accordingly, the area and the aperture ratio of the first light-emitting portion 8 for each light-emitting unit 2 of the light-emitting-unit unit 54 are larger than the area and the aperture ratio of the first light-emitting portion 8 for each light-emitting unit 2 of the light-emitting-unit unit 53.

When the light-emitting-unit unit 51 and the light-emitting-unit unit 54 are compared with each other in terms of the area and the aperture ratio of the first light-emitting portion 8 for each light-emitting unit 2, it is found that the light-emitting-unit unit 51 has larger values.

In order to form the first light-emitting portion 8 in a U shape without changing the arrangement of the second light-emitting portion 9 and the third light-emitting portion 10 in the light-emitting-unit unit 53 as much as possible, it is necessary to reduce the aperture ratio of the second light-emitting portion 9 and the aperture ratio of the third light-emitting portion 10 as in the light-emitting-unit unit 55.

An example related to the light-emitting-unit unit 55 is the light-emitting-unit unit 52. In the light-emitting-unit unit 52, the aperture ratio of the second light-emitting portion 9 and the aperture ratio of the third light-emitting portion 10 are the same as those of the light-emitting-unit unit 55 with respect to the light-emitting-unit unit 50. Accordingly, in the light-emitting-unit unit 52, the aperture ratio of the first light-emitting portion 8 is increased in various ways, such as by filling most of the missing portion 12 (see FIG. 7) of the first light-emitting portion 8 with the first light-emitting portion 8.

When the light-emitting-unit unit 52 and the light-emitting-unit unit 55 are compared with each other in terms of the area and the aperture ratio of the first light-emitting portion 8 for each light-emitting unit 2, it is found that the light-emitting-unit unit 52 has larger values.

In a case where the red subpixel, the green subpixel, and the blue subpixel are arranged in a so-called PenTile structure, the aperture ratio of the blue subpixel in each pixel is about 10%. On the other hand, in each of the light-emitting-unit units 50 to 52, the aperture ratio of each light-emitting unit 2 that can be used as a pixel in the first light-emitting portion 8 that can be used as a blue subpixel can be 30% or greater (about three times the aperture ratio of the PenTile structure).

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A display device comprising:
at least one light-emitting unit that is a quadrilateral in a plan view,
wherein the at least one light-emitting unit includes
a first light-emitting portion configured to emit light of a first color and disposed facing a portion including a first corner, a second corner, and a third corner of the quadrilateral,
a second light-emitting portion configured to emit light of a second color and disposed facing a fourth corner of the quadrilateral, and
a third light-emitting portion configured to emit light of a third color with a luminosity higher than both a luminosity of the first color and a luminosity of the second color, the third light-emitting portion being disposed closer to a center of the quadrilateral than the first light-emitting portion and the second light-emitting portion.

2. The display device according to claim 1,
wherein the second light-emitting portion and the third light-emitting portion are disposed on a common diagonal line of the quadrilateral.

3. The display device according to claim 1,
wherein a missing portion of the first light-emitting portion is formed facing any one side of the quadrilateral.

4. The display device according to claim 1,
wherein a portion of the first light-emitting portion disposed facing the first corner, a portion of the first light-emitting portion disposed facing the second corner, and a portion of the first light-emitting portion disposed facing the third corner are continuous with each other.

5. The display device according to claim 1,
wherein the first light-emitting portion is divided into a plurality of small regions electrically isolated from each other.

6. The display device according to claim 5,
wherein among the first light-emitting portion, the second light-emitting portion, and the third light-emitting portion, two adjacent light-emitting portions are set as a first target light-emitting portion and a second target light-emitting portion, and
a gap between the first target light-emitting portion and the second target light-emitting portion is non-emitting.

7. The display device according to claim 6,
wherein a minimum value of a separation distance between the first target light-emitting portion and the second target light-emitting portion is greater than a minimum value of a separation distance between two adjacent small regions of the plurality of small regions.

8. The display device according to claim 1,
wherein a light-emitting material layer including a material that emits light of the first color is formed substantially entirely in the quadrilateral.

9. The display device according to claim 8,
wherein a portion of the light-emitting material layer overlaps with a layer including a material that emits light of the second color or the third color.

10. The display device according to claim 1,
wherein a luminosity of the first color is lower than a luminosity of the second color.

11. The display device according to claim 1,
wherein the first color is blue.

12. The display device according to claim 11,
wherein the second color is red and the third color is green.

13. The display device according to claim 1,
wherein the light-emitting unit is one pixel.

14. The display device according to claim 1,
wherein in a plan view of the light-emitting unit, a shape of the first light-emitting portion, a shape of the second light-emitting portion, and a shape of the third light-emitting portion are each defined by a shape of a corresponding electrode.

15. The display device according to claim 1,
wherein the light-emitting unit includes a plurality of light-emitting units, and the plurality of light-emitting units are arranged in an identical orientation.

16. The display device according to claim 1,
wherein the light-emitting unit includes four light-emitting units, and
first light-emitting portions of the four light-emitting units are arranged to form a cross.

17. The display device according to claim 16,
wherein the second light-emitting portions of the four light-emitting units are disposed on a first circle centered on a center of the cross, and
the third light-emitting portions of the four light-emitting units are disposed on a second circle centered on the center of the cross.

18. The display device according to claim 3,
wherein a first light-emitting unit and a second light-emitting unit are provided, and
a first light-emitting portion of the first light-emitting unit and a second light-emitting portion of the second light-emitting unit face each other across a missing portion of the first light-emitting portion of the first light-emitting unit.
